(19) United States
(12) Patent Application Publication
(10) Pub. No.: US 2005/0179046 A1
(43) Pub. Date: Aug. 18, 2005

(54) P-type electrodes in gallium nitride-based light-emitting devices

(75) Inventors: Tchang-hun Oh, Sharon, MA (US); Brenda D. Dingle, Mansfield, MA (US); Bo Yang, Providence, RI (US); Ilya Libenzon, Wilmington, MA (US); William T. Roberts, North Attleboro, MA (US); Hong K. Choi, Sharon, MA (US); John C. C. Fan, Brookline, MA (US)

Correspondence Address: HAMILTON, BROOK, SMITH & REYNOLDS, P.C., 530 VIRGINIA ROAD, P.O. BOX 9133, CONCORD, MA, 01742-9133, US

(73) Assignee: Kopin Corporation, Taunton, MA (US)

(21) Appl. No.: 11/057,415

(22) Filed: Feb. 14, 2005

Related U.S. Application Data
(60) Provisional application No. 60/544,491, filed on Feb. 13, 2004.

(51) Int. Cl. H01L 29/22

(52) U.S. Cl. 257/94

(57) ABSTRACT

An improved p-type electrode for a p-type gallium-nitride based semiconductor material is disclosed that includes at least one layer of indium-tin-oxide. The electrode can include the indium-tin-oxide layer(s) such that at least one of the indium-tin-oxide layers is in contact with the p-type semiconductor layer. Alternatively, the electrode can further include a first electrode layer in contact with the p-type semiconductor layer. In this example, the indium-tin-oxide layer(s) is over the first electrode layer. The first electrode layer includes at least one metal selected from the group consisting of nickel oxide, molybdenum oxide, ruthenium oxide and zinc oxide, and/or at least one non-oxidizing metal.

### RELATED APPLICATION

This application claims the benefit of U.S. Provisional Application No. 60/544,491, filed on Feb. 13, 2004. The entire teachings of this application are incorporated herein by reference.

### BACKGROUND OF THE INVENTION

Recently, much attention has been focused on GaN-based compound semiconductors (e.g., InₓAl_{y}Ga_{1-x-y}N wherein x+y<1, 0≦x<1, and 0≦y<1) for blue, green, and ultraviolet light emitting diode (LED) applications. One important reason is that GaN-based LEDs have been found to exhibit efficient light emission at room temperature.

In general, GaN-based LEDs comprise a multilayer structure in which n-type and p-type GaN-based semiconductor layers are stacked on a substrate (most commonly on a sapphire substrate with the n-type GaN-based semiconductor layer in contact with the substrate), and InₓGa₁₋ₓN/GaN multiple quantum well layers are sandwiched between the p-type and n-type GaN layers. A number of methods for growing the multilayer structure are known in the art, including metalorganic chemical vapor deposition (MOCVD), molecular beam epitaxy (MBE) and hydride vapor phase epitaxy (HVPE).

Generally, p-type GaN-based semiconductor layers formed by growth methods, such as MOCVD, behave like a semi-insulating or high-resistive material. This is believed to result from hydrogen passivation caused by hydrogen that is present in the reaction chamber complexing with the p-type dopant, thus preventing the dopant from behaving as an active carrier. Typically, p-type GaN-based semiconductor materials are thermally annealed to activate the p-type carriers. However, even after thermal annealing, the resistivity of p-type GaN-based semiconductor materials remains relatively high, making it difficult to form a satisfactory ohmic contact with the material. In addition, there are few metals with a high work function comparable to the band gap and electron affinity of gallium nitride that will form a low resistance interface with gallium nitride. Due to aforementioned limited lateral conductivity of p-type materials, GaN-based light-emitting devices generally depend on a highly conductive p-type electrode with a good ohmic contact to the top GaN surface for spreading the current in lateral directions (see, for example, U.S. Pat. No. 6,847,052). Good ohmic contact to gallium nitride is desirable because the performance of gallium nitride-based devices, such as the operating voltage, is strongly influenced by the contact resistance.

Sapphire generally is used as the substrate for GaN-based LEDs because it is inexpensive and GaN-based semiconductor layers grown on a sapphire substrate are reasonably free of defects. However, sapphire is electrically insulative. Thus, electrodes cannot be mounted on the sapphire substrate, but must be formed directly on the n-type and p-type GaN-based semiconductor layers. In addition, since p-type GaN-based semiconductor layers have only moderate conductivity, a p-electrode typically is formed to cover substantially the entire surface of the p-type GaN-based semiconductor layer in a GaN-based LED in order to ensure uniform application of current to the entire layer and to obtain uniform light emission from the LED. However, this geometry requires that the light emitted by the LED be observed through the sapphire substrate or through a transparent p-electrode. Typically, light-transmitting electrodes transmit only 20 to 40% of the light emitted from the LED. Although sapphire has a high transmission coefficient, observation of the light emitted from the LED through the sapphire substrate requires a complicated packaging step. Thus, in order to decrease the cost of manufacture and increase the efficiency of GaN-based LEDs, it is desirable to develop p-type electrodes that have improved light transmission.

### SUMMARY OF THE INVENTION

An improved p-type electrode of the present invention that includes at least one layer of indium-tin-oxide provides a p-type electrode for a p-type GaN-based semiconductor material.

In one embodiment, the p-type electrode of the invention includes a layer of indium-tin-oxide that is in contact with the p-type semiconductor layer.

In another embodiment, the p-type electrode includes a first electrode layer in contact with the p-type semiconductor layer and an indium-tin-oxide layer over the first electrode layer. The first electrode layer includes at least one metal oxide selected from the group consisting of nickel oxide, molybdenum oxide, ruthenium oxide and zinc oxide, or at least one non-oxidizing metal. Preferably, the non-oxidizing metal is selected from the group consisting of gold, palladium and platinum.

In yet another embodiment, the first electrode layer includes at least one of the metal oxides and at least one of the non-oxidizing metals.

The p-type electrodes of the invention can be used to form a semiconductor device, such as a light-emitting diode (LED) device or a laser diode (LD) device. The semiconductor device of the invention comprises a substrate; a semiconductor device structure over the substrate; an n-type electrode in electrical contact with the n-type semiconductor layer; and a p-type electrode as described above, which is in electrical contact with the p-type semiconductor layer. The semiconductor device structure includes an n-type GaN-based semiconductor layer and a p-type GaN-based semiconductor layer over the n-type semiconductor layer.

The present invention also includes a method for producing a semiconductor device as described above. The method includes forming the GaN-based semiconductor device structure over the substrate, forming an n-type electrode in electrical contact with the n-type semiconductor layer, and forming such a p-type electrode as described above.

In one embodiment, the p-type electrode is formed by depositing a layer of indium-tin-oxide on the p-type semiconductor layer such that the indium-tin-oxide layer is in contact with the p-type semiconductor layer.

In another embodiment, the p-type electrode is formed by depositing a first metal layer on the p-type semiconductor layer such that the first metal layer is in contact with the p-type semiconductor layer. A layer of indium-tin-oxide is deposited over the first metal layer. The method further includes subjecting at least the first metal layer to an annealing treatment in the presence of oxygen. The first metal layer includes at least one metal selected from the group consisting of nickel, molybdenum, ruthenium, zinc and non-oxidizing metals. Preferably, the non-oxidizing metals include gold, palladium and platinum.

In yet another embodiment, the p-type electrode is formed by depositing a metal-oxide layer on the p-type semiconductor layer such that the metal-oxide layer is in contact with the p-type semiconductor layer. The metal-oxide layer includes at least one metal oxide selected from the group consisting of nickel oxide, molybdenum oxide, ruthenium oxide and zinc oxide. A layer of indium-tin-oxide is deposited over the metal-oxide layer. The method further includes subjecting the metal-oxide and indium-tin-oxide layers to an annealing treatment.

The p-type electrodes of the invention are highly light transmissive and electrically conductive. In addition, the p-type electrodes of the invention form a low-resistance ohmic contact to the underlying p-type GaN-based semiconductor layer of the GaN-based semiconductor devices.

### BRIEF DESCRIPTION OF THE DRAWINGS

FIG. 1 shows a schematic cross-sectional view of a semiconductor device of the invention.

FIGS. 2A-2C show schematic cross-sectional views of p-type electrodes of the semiconductor device of FIG. 1.

### DETAILED DESCRIPTION OF THE INVENTION

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

In general, a semiconductor device contains multiple semiconductor layers grown epitaxially on a substrate, such as sapphire. Alternatively, the semiconductor layers can be grown domain-epitaxially as described in U.S. 2004/0072381 A1, the entire teachings of which are incorporated herein by reference. The growth of semiconductor layers can be achieved by a number of widely-known crystal growth techniques in the art, including metalorganic chemical vapor deposition (MOCVD), molecular beam epitaxy (MBE), and hydride vapor phase epitaxy (HVPE). The epitaxial layers are stacked in such a way to form a vertical p-n junction structure, which is typically achieved by stacking n-type layers and then p-type layers in sequence on top of a substrate. The device described in the present invention can have light emission either from the top surface of the semiconductor layers or from the bottom of the substrate. Typically, in the GaN-based light-emitting devices of the invention, light emission occurs from the top surface of the GaN-based semiconductor layers. The substrate can be an insulating substrate such as sapphire or a conducting substrate such as silicon carbide. Preferably, the device of the present invention is a gallium nitride (GaN)-based device.

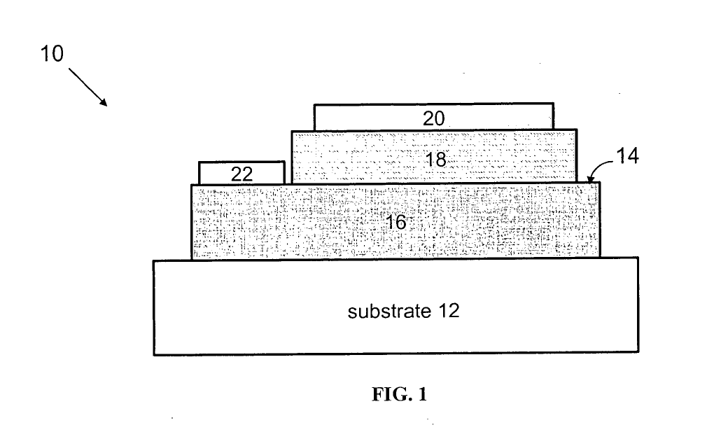

FIG. 1 shows a typical embodiment of the semiconductor device of the invention. As shown, semiconductor device 10 includes substrate 12, semiconductor device structure 14, p-type electrode 20 and n-type electrode 22. Semiconductor device structure 14 includes semiconductor layer(s) 16 over substrate 12 and p-type semiconductor layer 18 over semiconductor layer(s) 16. Semiconductor layer(s) 16 can represent an n-type semiconductor layer or a stack of p-type and n-type semiconductor layers where the top layer is an n-type semiconductor layer. In a preferred embodiment, semiconductor layer(s) 16 includes an active layer, such as a single quantum-well structure or multiple quantum-well structure.

P-type electrode 20 includes at least one indium-tin-oxide layer. At least one of the indium-tin-oxide layers includes indium and tin in a ratio of tin-to-indium in a range of between about 1% and about 20% by weight. Typically, p-type electrode 20 is substantially light transmissive. As used herein, “substantially light transmissive,” means that the electrode transmits at least 1% of the light emitted from the gallium nitride-based semiconductor device therethrough. Preferably, p-type electrode 20 typically transmits at least about 40% of the light emitted from the gallium nitride-based semiconductor device. More preferably, p-type electrode 20 transmits more than about 60% of the light emitted from the gallium nitride-based semiconductor device.

As discussed above, in the GaN-based light-emitting devices, due to a poor lateral conductivity of the p-type GaN-based materials, it is advantageous for the p-type electrode formed on top of the p-type GaN layer to provide a proper level of lateral current spreading. To ensure a sufficient level of lateral current spread, p-type electrode 20 typically covers a substantial portion, preferably greater than about 50%, of the top GaN surface.

In addition to the substantial coverage of the surface, p-type electrode 20 has a high electrical conductivity, which is characterized in terms of a sheet resistance of the layer, to reduce a voltage drop due to the current spread. Preferably, p-type electrode 20 has a sheet resistance of lower than about 50 Ω. P-type electrode 20 also has a low-resistance ohmic contact to the underlying p-type GaN surface, reducing the operating voltage of the devices. Preferably, a contact resistivity of the ohmic contact formed by p-type electrode 20 is lower than about 5×10⁻² Ωcm⁻².

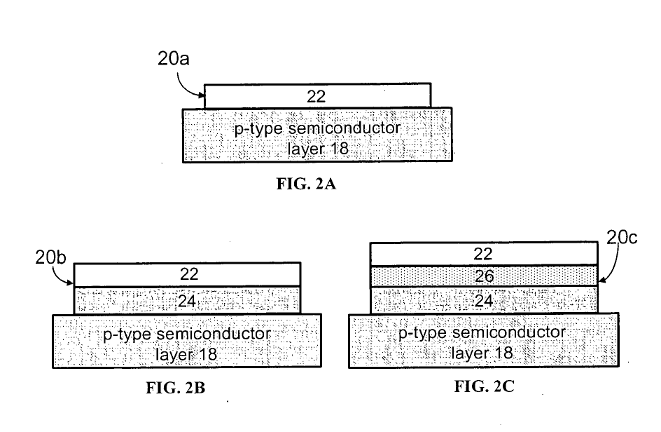

FIGS. 2A-2C show schematic cross-sectional views of the p-type electrodes of the invention, 20a-20c (collectively p-type electrode 20).

In one embodiment, p-type electrode 20 includes indium-tin-oxide layer 22, producing p-type electrode 20a that is in contact with p-type semiconductor layer 18, as shown in FIG. 2A.

In the example of FIG. 2B, p-type electrode 20b includes first electrode layer 24 in contact with p-type semiconductor layer 18 and indium-tin-oxide layer 22 over first electrode layer 24. In one embodiment, first electrode layer 24 is a metal-oxide layer that includes at least one metal oxide selected from the group consisting of nickel oxide, molybdenum oxide, ruthenium oxide and zinc oxide. Preferably, the metal-oxide layer includes nickel oxide. In another embodiment, first electrode layer 24 is a non-oxidizing metal layer that includes at least one non-oxidizing metal. As used herein, a “non-oxidizing metal” means any metal that does not go through an oxidation reaction with oxygen, such as gold, palladium and platinum, or a combination thereof. Preferably, the non-oxidizing metal is gold. In yet another embodiment, first electrode layer 24 includes at least one metal oxide and at least one non-oxidizing metal. The metal oxide can be nickel oxide, molybdenum oxide, ruthenium oxide, zinc oxide or a combination thereof. Preferably, the metal oxide is nickel oxide and the non-oxidizing metal is gold.

In the examples of FIG. 2C, p-type electrode 20c further includes second electrode layer 26 between first electrode layer 24 and indium-tin-oxide layer 22. In one example, second electrode layer 26 includes at least one metal oxide selected from the group consisting of nickel oxide, molybdenum oxide, ruthenium oxide and zinc oxide, or at least one of the non-oxidizing metals. In another example, second electrode layer 26 includes at least one of the metal oxides and at least one of the non-oxidizing metals. In a preferred embodiment, first electrode and second electrode layers 24 and 26 have different metal components from each other. For example, first electrode layer 24 is the metal-oxide layer and second electrode layer 26 is the non-oxidizing metal layer. Preferably, the metal-oxide layer includes nickel oxide and the non-oxidizing metal layer includes gold.

In some embodiments, p-type electrode 20 includes multiple metal-oxide layers and/or non-oxidizing metal layers. In these embodiments, each of first electrode layer 24 and second electrode layer 26 represents multiple layers of the metal-oxide(s) or non-oxidizing metal(s). At least one of the metal-oxide layers or non-oxidizing metal layers is in contact with p-type semiconductor layer 18.

In any embodiments described above, p-type electrode 20 of the invention can include multiple indium-tin-oxide layers. For example, referring back to FIGS. 2A-2C, layer 22 can represent multiple indium-tin-oxide layers, where at least one of the indium-tin-oxide layers is in contact with p-type semiconductor layer 18 in electrode 20a, or in contact with first electrode layer 24 or second electrode layer 26 in electrodes 20b and 20c, respectively.

When p-type electrode 20 includes multiple indium-tin-oxide layers, preferably, each of the indium-tin-oxide layers has a different ratio of tin-to-indium by weight.

To prepare p-type electrodes of the invention, an indium-tin-oxide layer(s) and a metal layer(s) which later form the first or second electrode layer are deposited over a p-type gallium nitride-based material, such as p-type gallium nitride (p-GaN), by evaporation, sublimation or other techniques known to those skilled in the art.

The layers of indium-tin-oxide can be deposited either reactively (in the presence of oxygen) or non-reactively (in an inert atmosphere substantially free of oxygen). The introduction of reactive gases, such as oxygen, during the deposition is believed to improve the light transmission of the electrode. Thus, preferably, the indium-tin-oxide layers are deposited in the presence of oxygen. The concentration of oxygen is preferably in a range of between about 0.1% and about 10%.

The layers of indium-tin-oxide can be deposited under different conditions to make each layer of indium-tin-oxide have different characteristics, e.g., different ratios of tin-to-indium by weight. For example, the ratio of tin to indium by weight can be adjusted to have from about 1% to about 20% for each indium-tin-oxide layer. Also, when multiple indium-tin-oxide layers are included in electrode 20, preferably, each of the indium-tin-oxide layers is grown in a different oxygen concentration.

The thickness of the indium-tin-oxide layer may vary depending upon the structures of the p-type electrodes. For example, in a p-type electrode as shown in FIG. 2A, typically, the thickness of the indium-tin-oxide layer in contact with the p-type semiconductor layer is in a range of between about 100 Å and about 5000 Å, in particular, 100 Å and about 2000 Å. In a p-electrode as shown in FIGS. 2B and 2C, the typical thickness of the indium-tin-oxide layer is in a range of between about 50 Å and about 500 Å. When an additional indium-tin-oxide layer is deposited on this indium-tin-oxide layer, typically, the thickness of the additional layer of indium-tin-oxide is in a range of between about 1000 Å and about 5000 Å.

Referring back to FIGS. 2B and 2C, p-type electrodes, 20b and 20c, are formed by depositing a first metal layer on p-type semiconductor layer 18. The first metal layer includes at least one metal selected from the group consisting of nickel, molybdenum, ruthenium, zinc and the non-oxidizing metals. The thickness of the first metal layer is typically in a range of between about 5 Å and about 200 Å. Indium-tin-oxide layer 22 is then deposited, as described above, over the first metal layer.

In some embodiments, a second metal layer is deposited on the first metal layer, prior to depositing indium-tin-oxide layer 22. The second metal layer includes at least one metal selected from the group consisting of nickel, molybdenum, ruthenium, zinc and the non-oxidizing metals. In one example, the first and second metal layers are intermixed during an annealing step or deposited simultaneously to produce first electrode layer 24 that includes at least two different components, for example, at least one of the metal oxides and at least one of the non-oxidizing metals. In this example, the first and second metal layers can be deposited sequentially or simultaneously. In another example, the first metal layer produces first electrode layer 24, and the second metal layer produces second electrode layer 26. For example, the first metal layer produces the metal-oxide layer and second metal layer produces the non-oxidizing metal layer. In this example, the first metal and second metal layers are sequentially deposited.

The thickness of the second metal layer is typically in a range of between about 5 Å and about 100 Å. When the first and second metal layers deposited simultaneously and form first electrode 24, as shown in FIG. 2B, the thickness of the metal layers are typically in a range of between about 50 Å and about 300 Å.

The metal layer(s) and optionally indium-tin-oxide layer are subjected to an annealing treatment in the presence of oxygen. In one embodiment, the annealing treatment is performed before the indium-tin-oxide layer is deposited on either the first or second metal layer. In another embodiment, the annealing step is performed after deposition of the indium-tin-oxide layer, whereby both the metal and indium-tin-oxide layers are subject to the annealing treatment. When the first and second metal layers are employed, the first and second metal layers can be annealed separately or simultaneously.

For electrode 20a, indium-tin-oxide layer 22 can be subjected to an annealing treatment. The annealing treatment can be performed in the presence or without oxygen. Preferably, the annealing treatment is performed in the presence of oxygen.

When the metal layer includes an oxidizing metal(s), such as nickel, molybdenum, ruthenium and zinc, during the annealing treatment, the oxidizing metal(s) is substantially oxidized to a metal oxide(s), such as nickel oxide, molybdenum oxide, ruthenium oxide and zinc oxide. During the annealing treatment, a substantial portion, preferably more than about 50%, of the oxidizing metals included in the metal layers are oxidized to form a metal oxide. The metal oxide formed behaves as a p-type semiconductor (e.g., p-NiO or p-ZnO). As used herein, an “oxidizing metal” means any metal that can undergo an oxidation reaction with oxygen. On the other hand, when the metal layer includes a non-oxidizing metal(s), such as gold, palladium and platinum, the non-oxidizing metal(s) is not oxidized during the annealing treatment.

The annealing step is typically performed at a temperature at least about 350° C. For the embodiments where the first and second metal layers are deposited sequentially or simultaneously on the p-type semiconductor layer, the annealing temperature is preferably at a temperature in a range of between about 400° C. and about 600° C., more preferably between 300° C. and about 500° C. For the embodiment where only a layer of indium-tin-oxide is deposited on the p-type semiconductor layer, the annealing temperature is preferably in a range of between about 500° C. and about 900° C.

The amount of oxygen present in the annealing environment can be greater than about 1% and may be as high as 100%. The annealing environment can be air or a controlled environment such as 65% oxygen/35% nitrogen. Typically, the oxygen concentration is in a range of between about 1% and 60%. In particular, in the embodiment where the indium-tin-oxide layer is deposited directly on the p-type semiconductor layer, the oxygen concentration is preferably in a range of between about 10% and about 60%. In the embodiments where first and second indium-tin-oxide layers are deposited on any of the first metal layer, second metal layer and p-type semiconductor layer, the second indium-tin-oxide layer is preferably annealed in the presence of oxygen of a concentration in a range of between about 1% and about 10%.

In yet another embodiment where p-type electrode 20 includes first electrode layer 24 that includes at least one of the metal oxides, p-type electrode 20 can be made by depositing the metal oxide(s) on p-type semiconductor layer 18 and then by depositing indium-tin-oxide layer 22 over the metal-oxide layer. The metal oxide layer can be deposited by evaporation, sublimation or other techniques known to those skilled in the art. In this embodiment, the metal-oxide and indium-tin-oxide layers can be annealed in the presence or without oxygen. A typical annealing temperature is at least about 350° C., preferably in a range of between about 400° C. and about 600° C., more preferably in a range of between about 300° C. and about 500° C. During the annealing treatment, intermixing between the elements of the deposited layers can occur. When oxygen is used for the annealing treatment, the preferred oxygen concentration is in a range of between about 10 and about 60%.

In the embodiments where a second indium-tin-oxide layer is deposited on a first indium-tin-oxide layer deposited over any of the first metal layer, second metal layer, metal-oxide layer and p-type semiconductor layer, the second indium-tin-oxide layer can be subsequently annealed after the underlying layers are annealed. The annealing step can be carried out either in the presence or without oxygen. When oxygen is used, the second indium-tin-oxide layer is preferably annealed in the presence of oxygen of a concentration in a range of between about 1% and about 10%. A typical annealing temperature for the second indium-tin-oxide layer depends on the underlying layers. For example, a p-type electrode where the first indium-tin-oxide layer is in contact with the p-type semiconductor layer, the second indium-tin-oxide layer is annealed preferably at a temperature in a range of between about 500° C. and about 900° C. In an example where the first indium-tin-oxide layer is over the metal and/or metal-oxide layers, the second indium-tin-oxide layer is annealed preferably at a temperature in a range of between about 300° C. and about 500° C.

The annealing steps described above can be preformed in a furnace, rapid thermal annealing, or on a hot plate. Typical annealing time is about 30 seconds to about 1 hour.

As used herein, a gallium nitride-based semiconductor material is a material having the formula InₓAl_{y}Ga_{1-x-y}N, wherein x+y<1, 0≦x<1, and 0≦y<1. Gallium nitride-based semiconductor materials are usually grown by a vapor phase growth method such as metalorganic chemical vapor deposition (MOCVD or MOVPE, hydride chemical vapor deposition (HDCVD), or molecular beam epitaxy (MBE). Generally, a gallium nitride-based semiconductor material is an n-type material even when no n-type dopant is included in the material since nitrogen lattice vacancies are created during crystal growth. Thus, an n-type gallium nitride-based semiconductor material may not include an n-type dopant. However, an n-type gallium nitride-based semiconductor typically exhibits better conductivity when the material includes an n-type dopant. n-Type dopants for gallium nitride-based semiconductor materials include Group IV elements such as silicon, germanium and tin, and Group VI elements such as selenium, tellurium and sulfur.

A p-type gallium nitride-based semiconductor material is a gallium nitride-based semiconductor material that includes a p-type dopant. The p-type dopants (also called an acceptor) for gallium nitride-based semiconductor materials include Group II elements such as cadmium, zinc, beryllium, magnesium, calcium, strontium, and barium. Preferred p-type dopants are magnesium and zinc. Typically, during growth of the gallium nitride-based semiconductor material gaseous compounds containing hydrogen atoms are thermally decomposed to form the semiconductor material. The released hydrogen atoms, which are present mainly as protons, become trapped in the growing semiconductor material, and combine with p-type dopant inhibiting their acceptor function. To improve the conductivity of a p-type gallium nitride-based semiconductor material, the material may be placed in a high electric field, typically above 10,000 volts/cm for about 10 minutes or more. The protons trapped in the semiconductor material are drawn out of the material to the negative electrode, thereby activating the function of the p-type dopants (see U.S. patent application Ser. No. 10/127,345, the entire teachings of which are incorporated herein by reference). Alternatively, the conductivity of the p-type gallium nitride-based semiconductor material can be improved by annealing the material at a temperature above 600° C. in a nitrogen environment for 10 minutes or more (see U.S. Pat. No. 5,306,662, the entire teachings of which are incorporated herein by reference).

As described above, a gallium nitride-based semiconductor structure includes a p-type gallium nitride-based semiconductor layer and n-type gallium nitride-based semiconductor layer. The p-type gallium nitride-based semiconductor layer is generally grown over the n-type gallium nitride-based semiconductor layer. The n-type and p-type semiconductor layers can be in direct contact with each other or, alternatively, an active region can be sandwiched between the n-type and p-type gallium nitride-based semiconductor layers. An active region can have a single quantum-well structure or a multiple quantum-well structure. An active region having a single quantum-well structure has a single layer (i.e., the well layer) formed of a gallium nitride-based semiconductor material having a lower band-gap than the n-type and p-type gallium nitride-based semiconductor layers sandwiching it. An active region having a multiple quantum-well structure includes multiple well layers alternately stacked with multiple layers that have a higher band-gap than the well layers (i.e., barrier layers). The outer most layer of the active region closest to the n-type gallium nitride-based semiconductor layer is a well layer and has a smaller band-gap than the n-type gallium nitride-based semiconductor layer. The outer most layer of the active region closest to the p-type gallium nitride-based semiconductor layer can be a well layer or a barrier layer and can have a band-gap that is larger or smaller than the p-type gallium nitride-based semiconductor layer. Typically, the thickness of a well layer in a quantum-well structure is about 70 Å or less, and the barrier layers are about 150 Å or less. Generally, the well layers and barrier layers in a quantum-well structure are not intentionally doped.

The phrase “ohmic contact,” as used herein, refers to a region where two materials are in contact, which has the property that the current flowing through the region is proportional to the potential difference across the region.

It is believed that during the annealing process epitaxial layers, such as ITO (indium-tin-oxide)/Au-p-NiO/p-GaN or ITO/p-NiO/Au/p-GaN layers, are formed by domain matching epitaxy where integral multiples of lattice planes match across the film-substrate interface. For example, epitaxial gold, which has a lattice constant of 0.408 nm, grown on top of p-type gallium nitride, provides a template for the growth of nickel oxide, which has a lattice constant 0.417 nm, via lattice matching epitaxy. Nickel oxide can grow over the top of gold as well as laterally to contact the p-type gallium nitride semiconductor layer, providing an ohmic contact to p-type gallium nitride.

### EXEMPLIFICATION

### Example 1

### Preparation of Semiconductor Device Structure

The semiconductor device structure described in this invention was grown on a c-sapphire substrate by low-pressure MOCVD. The first deposited layer was a 20 nm-thick GaN nucleation layer, which was followed by a 4 μm-thick, silicon-doped (doping concentration of about 10¹⁸ cm⁻³) n-type GaN layer. The next layers were multiple quantum well active layers made of InₓGa₁₋ₓN/GaN (0<x<0.5) layers. The last layer was a 0.6 μm-thick magnesium-doped p-type GaN layer. The doping concentration of the top p-type GaN layer was typically higher than 10¹⁹ cm⁻³.

### Example 2

### P-Type Electrode Comprising Layers of Nickel Oxide, Gold, and Indium-Tin-Oxide

For forming a p-type electrode, a 100 Å thick nickel layer was first deposited on top of the p-type GaN layer. A 50 Å thick gold layer and then a 200 Å thick indium-tin-oxide layer were deposited in sequence on top of the deposited layer of nickel. The depositions were carried out in a conventional sputtering system with a reactive deposition process for indium-tin-oxide. The whole layers were annealed in an oxygen environment at 550° C. for 20 minutes using a conventional tube furnace. A 2000 Å thick indium-tin-oxide layer was then deposited to increase the conductivity of the resulting p-type electrode. After deposition, a rapid thermal annealing process was carried out at 450° C. for 10 minutes. The p-type electrode formed an ohmic contact to the underlying p-type GaN surface with a contact resistivity of lower than 5×10⁻³Ω-cm². The measured sheet resistance of the electrode was lower than 40Ω. The finished electrode transmitted more than 80% of incident light.

### Example 3

### P-Electrode Comprising Nickel Oxide and Indium-Tin-Oxide

A 100 Å thick nickel layer was first deposited on top of the p-type GaN layer. A 200 Å thick indium-tin-oxide layer was deposited on top of the deposited layer of nickel. The depositions were carried out in a conventional sputtering system with a reactive deposition process for indium-tin-oxide. The whole layers were annealed in an oxygen environment at 550° C. for 20 minutes using a conventional tube furnace. A 2000 Å thick indium-tin-oxide layer was deposited to increase the conductivity of the resulting p-type electrode. After deposition, a rapid thermal annealing process was carried out at 450° C. for 10 minutes. The p-type electrode formed an ohmic contact to the underlying p-type GaN surface with a contact resistivity of lower than 1×10⁻² Ω-cm². The measured sheet resistance of the electrode was lower than 40Ω. The finished electrode transmitted more than 85% of incident light.

### Example 4

### P-Electrode Comprising Indium-Tin-Oxide Only

A 1500 Å thick indium-tin-oxide layer was deposited on top of the p-type GaN layer. The deposition was carried out in a conventional sputtering system under a non-reactive condition. After deposition, the layer was annealed in a non-oxygen environment at 800° C. for 2 minutes using a rapid thermal anneal apparatus. The p-type electrode formed an ohmic contact to the underlying p-type GaN surface with a contact resistivity of lower than 5×10⁻² Ω-cm². The measured sheet resistance of the electrode was lower than 30Ω. The finished electrode transmitted more than 80% of incident light.

Equivalents

While this invention has been particularly shown and described with references to preferred embodiments thereof, it will be understood by those skilled in the art that various changes in form and details may be made therein without departing from the scope of the invention encompassed by the appended claims.

1. A semiconductor device comprising:
a) a semiconductor device structure over a substrate, the device structure comprising an n-type gallium nitride-based semiconductor layer, and a p-type gallium nitride-based semiconductor layer over the n-type semiconductor layer;
b) an n-type electrode in electrical contact with the n-type semiconductor layer; and
c) a p-type electrode in electrical contact with the p-type semiconductor layer, the p-type electrode including a layer of indium-tin-oxide that is in contact with the p-type semiconductor layer.

2. The device of claim 1, wherein the indium-tin-oxide layer includes indium and tin in a ratio of tin-to-indium in a range of between about 1% and about 20% by weight.

3. The device of claim 2, wherein the p-side electrode transmits more than about 60% of incident light.

4. The device of claim 3, wherein the p-type electrode has a resistivity of an ohmic contact to the p-type semiconductor layer lower than about 5×10⁻² Ωcm⁻².

5. The device of claim 2, wherein the p-type electrode includes multiple indium-tin-oxide layers, each of the indium-tin-oxide layers having a different ratio of tin-to-indium by weight.

6. A semiconductor device comprising:
a) a semiconductor device structure over a substrate, the device structure comprising an n-type gallium nitride-based semiconductor layer, and a p-type gallium nitride-based semiconductor layer over the n-type semiconductor layer;
b) an n-type electrode in electrical contact with the n-type semiconductor layer; and
c) a p-type electrode in electrical contact with the p-type semiconductor layer that includes:
i) a first electrode layer that is in contact with the p-type semiconductor layer, the first electrode layer including at least one metal oxide selected from the group consisting of nickel oxide, molybdenum oxide, ruthenium oxide and zinc oxide, and/or at least one non-oxidizing metal; and
ii) an indium-tin-oxide layer over the first electrode layer.

7. The device of claim 6, wherein the non-oxidizing metal is selected from the group consisting of gold, palladium and platinum.

8. The device of claim 7, wherein the indium-tin-oxide layer includes indium and tin in a ratio of tin-to-indium in a range of between about 1% and about 20% by weight.

9. The device of claim 8, wherein the p-type electrode transmits more than about 60% of incident light.

10. The device of claim 9, wherein the p-type electrode has a resistivity of an ohmic contact to the p-type semiconductor layer lower than about 5×10⁻² Ωcm⁻².

11. The device of claim 8, wherein the first electrode layer includes nickel oxide.

12. The device of claim 11, wherein the p-type electrode includes multiple indium-tin-oxide layers over the first electrode layer, each of the indium-tin-oxide layers having a different ratio of tin-to-indium by weight.

13. The device of claim 8, wherein the first electrode layer includes gold.

14. The device of claim 8, wherein the first electrode layer includes nickel oxide and gold.

15. The device of claim 14, wherein the p-type electrode includes multiple indium-tin-oxide layers over the first electrode layer, each of the indium-tin-oxide layers having a different ratio of tin-to-indium by weight.

16. The device of claim 8, wherein the p-type electrode further includes a second electrode layer between the first electrode and indium-tin-oxide layers, the second electrode layer including at least one of the metal oxides and/or at least one the non-oxidizing metals.

17. The device of claim 16, wherein the first electrode layer includes at least one of the metal oxides and the second electrode layer includes at least one of the non-oxidizing metals.

18. The device of claim 17, wherein the first electrode layer includes nickel-oxide.

19. The device of claim 18, wherein the second electrode layer includes gold.

20. The device of claim 19, wherein the p-type electrode includes multiple indium-tin-oxide layers over the second electrode layer, each of the indium-tin-oxide layers having a different ratio of tin-to-indium by weight.

21. A method for producing a semiconductor device, comprising:
forming a semiconductor device structure over a substrate, the device structure comprising an n-type gallium nitride-based semiconductor layer, and a p-type semiconductor gallium nitride-based semiconductor layer over the n-type semiconductor layer;
forming an electrode in electrical contact with the n-type semiconductor layer;
depositing a layer of indium-tin-oxide that is in contact with the p-type semiconductor layer to form a p-type electrode in electrical contact with the p-type semiconductor layer.

22. The method of claim 21, wherein the indium-tin-oxide layer includes tin and indium in a ratio of tin-to-indium in a range of between about 1% and about 20% by weight.

23. The method of claim 22, wherein the indium-tin-oxide layer is deposited in the presence of oxygen.

24. The method of claim 23, wherein the oxygen concentration is in a range of between about 0.1% and about 10%.

25. The method of claim 22, wherein the indium-tin-oxide layer is deposited in an inert atmosphere.

26. The method of claim 22, wherein the p-type electrode includes multiple indium-tin-oxide layers, each of the indium-tin-oxide layers having a different ratio of tin-to-indium by weight.

27. The method of claim 22, wherein the p-type electrode includes multiple indium-tin-oxide layers, each of the indium-tin-oxide layers being deposited in a different oxygen concentration.

28. A method for producing a semiconductor device, comprising:
forming a semiconductor device structure over a substrate, the device structure comprising an n-type gallium nitride-based semiconductor layer, and a p-type semiconductor gallium nitride-based semiconductor layer over the n-type semiconductor layer;
forming an n-type electrode in electrical contact with the n-type gallium nitride-based semiconductor layer;
depositing a first metal layer that is in contact with the p-type semiconductor layer, the first metal layer including at least one metal selected from the group consisting of nickel, molybdenum, ruthenium, zinc and non-oxidizing metals;
depositing a layer of indium-tin-oxide over the first metal layer; and
subjecting at least the first metal layer to an annealing treatment in the presence of oxygen to form a p-type electrode in contact with the p-type semiconductor layer.

29. The method of claim 28, wherein both the first metal and indium-tin-oxide layers are subjected to the annealing treatment.

30. The method of claim 28, wherein the non-oxidizing metals are selected from the group consisting of gold, palladium and platinum.

31. The method of claim 30, wherein the indium-tin-oxide layer includes tin and indium in a ratio of tin-to-indium in a range of between about 1% and about 20% by weight.

32. The method of claim 31, wherein the first metal layer includes at least one metal selected from the group consisting of nickel, molybdenum, ruthenium and zinc.

33. The method of claim 32, wherein the p-type electrode includes multiple indium-tin-oxide layers, each of the indium-tin-oxide layers having a different ratio of tin-to-indium by weight.

34. The method of claim 32, wherein the p-type electrode includes multiple indium-tin-oxide layers, each of the indium-tin-oxide layers being deposited in a different oxygen concentration.

35. The method of claim 32, wherein both the first metal and indium-tin-oxide layers are subjected to the annealing treatment.

36. The method of claim 35, wherein the temperature of the annealing treatment is conducted at a temperature of at least about 350° C.

37. The method of claim 36, wherein at least about 50% of the first metal layer is oxidized to form a metal-oxide layer.

38. The method of claim 37, wherein the metal-oxide layer includes nickel oxide.

39. The method of claim 30, further including depositing a second metal layer between the first metal and indium-tin-oxide layers, wherein the first metal layer includes at least one metal selected from the group consisting of nickel, molybdenum, ruthenium and zinc, and the second metal layer includes at least one metal selected from the group consisting of gold, palladium and platinum.

40. The method of claim 39, wherein the first and second metal layers are deposited simultaneously.

41. The method of claim 40, wherein the annealing step of the first metal layer includes annealing both the first and second metal layers.

42. The method of claim 39, wherein the p-type electrode includes multiple indium-tin-oxide layers over the second metal layer, each of the indium-tin-oxide layers having a different ratio of tin-to-indium by weight.

43. The method of claim 41, wherein the p-type electrode includes multiple indium-tin-oxide layers over the second metal layer, each of the indium-tin-oxide layers being deposited in a different oxygen concentration.

44. The method of claim 39, wherein both the first and second metal layers and indium-tin-oxide layer are subjected to the annealing treatment.

45. The method of claim 44, wherein the temperature of the annealing treatment is conducted at a temperature of at least about 350° C.

46. The method of claim 45, wherein at least about 50% of the first metal layer is oxidized to form a metal oxide layer.

47. The method of claim 46, wherein the metal-oxide layer includes nickel oxide.

48. The method of claim 47, wherein the second metal layer includes gold.

49. A method for producing a semiconductor device, comprising:
forming a semiconductor device structure over a substrate, the device structure comprising an n-type gallium nitride-based semiconductor layer, and a p-type semiconductor gallium nitride-based semiconductor layer over the n-type semiconductor layer;
forming an n-type electrode in electrical contact with the n-type gallium nitride-based semiconductor layer;
depositing a metal-oxide layer that is in contact with the p-type semiconductor layer, the metal-oxide layer including at least one metal-oxide selected from the group consisting of nickel oxide, molybdenum oxide, ruthenium oxide and zinc oxide; and
depositing a layer of indium-tin-oxide over the metal-oxide layer; and
subjecting the metal-oxide and indium-tin-oxide layers to an annealing treatment to form a p-type electrode in contact with the p-type semiconductor layer.

50. The method of claim 49, wherein the annealing treatment is performed in the presence of oxygen.
